(19) United States
(12) Patent Application Publication
(10) Pub. No.: US 2002/0142617 A1
(43) Pub. Date: Oct. 3, 2002

(54) Method for evaluating a wafer cleaning operation

(76) Inventor: Leslie G. Stanton, O'Fallon, MO (US)

Correspondence Address: SENNIGER POWERS LEAVITT AND ROEDEL, ONE METROPOLITAN SQUARE, 16TH FLOOR, ST LOUIS, MO, 63102, US

(21) Appl. No.: 09/817,929

(22) Filed: Mar. 27, 2001

(51) Int. Cl. H01L 21/302

(52) U.S. Cl. 438/749

(57) ABSTRACT

The present invention is a method for evaluating the particulate evacuating effectiveness of a wafer cleaning operation in which a cleaning liquid flows in a cleaning tank in contact with wafers. A test wafer and a seed wafer with contaminant particles on its surface are immersed into the cleaning liquid within the cleaning tank. The test wafer, contaminant particles and cleaning liquid are selected such that the zeta potentials which develop at the surface of the test wafer and contaminant particles liberated from the seed wafer into the cleaning liquid are of opposite polarity. The opposite zeta potentials enhance the deposition of the seed particles onto the surface of the test wafer. The test wafer is removed from the cleaning liquid, dried and inspected to produce a plot of the number and location of the contaminant particles deposited on the test wafer.

### BACKGROUND OF THE INVENTION

The present invention relates generally to a method for evaluating the effectiveness of a cleaning operation for removing contaminants from semiconductor wafers. More particularly, the present invention relates to a method for evaluating the particle evacuating effectiveness of a wafer cleaning operation in which a cleaning liquid flows in a cleaning tank in contact with wafers to remove contaminant particles from the surface of the wafers.

The manufacture of semiconductor wafers includes numerous processing operations including growing an ingot, slicing wafers from the ingot and lapping, grinding, etching, polishing and cleaning the wafers. Typically, the wafers are cleaned more than once during the manufacturing process. For example, wafers are usually cleaned between lapping and etching steps and again after final polishing to remove contaminants such as silicon particles, abrasive particles (e.g., alumina lapping grit and silica polishing media), foreign metals (e.g., iron, zinc and aluminum) and organic compounds from the wafer surface. Cleaning wafers after final polishing may comprise ten or more steps, including alkaline cleaning, acid cleaning, rinsing and drying. If conducted in an effective manner, cleaning may reduce the particle count on the front side of a polished 200 mm wafer from about 1 to 3 million particles exceeding about 0.2 μm LSE in diameter to about 15 or fewer particles exceeding about 0.2 μm LSE in diameter.

Typically, one or more of the cleaning operations during wafer manufacture include immersing the wafers in a cleaning liquid circulating in a cleaning tank. Cleaning liquids may contain, for example, a mixture of ammonia, hydrogen peroxide and deionized water (commonly referred to as SC1), a mixture of hydrochloric acid, hydrogen peroxide and deionized water (commonly referred to as SC2), hydrofluoric acid, citric acid, or deionized water. Particles liberated from the surface of a wafer as a result of immersion in the cleaning liquid are preferably evacuated from the tank in the flow of cleaning liquid exiting the tank so that the particles do not re-deposit on the wafers.

However, it is known that such cleaning baths are not always effective at removing particles from the surfaces of wafers and/or evacuating particles liberated from the surface of the wafers before the particles migrate through the cleaning liquid and re-deposit on the wafers (i.e., cross-contamination). Shortcomings in the particle evacuation efficacy of a wafer cleaning bath may be attributable to a variety of factors, including: the velocity of cleaning liquid flowing in the cleaning tank (either too fast or too slow), eddy currents and other disadvantageous flow patterns in the cleaning liquid due to improper positioning of liquid inlets and outlets in the cleaning tank and so-called blind spots in megasonic systems intended to enhance wafer cleaning in the bath. If integrated circuits are fabricated on a wafer surface with an excessive concentration of particulate impurities, the quality and performance of these circuits may be greatly diminished. As the semiconductor industry strives toward higher density chips with lower defect densities, effective wafer cleaning processes are essential. Accordingly, methods for evaluating the effectiveness of semiconductor wafer cleaning operations are known. For example, a comparison of particle counts on the surface of intentionally contaminated semiconductor wafers and bare silicon wafers prior to and after immersing a carrier containing both types of wafers in a cleaning bath has been used to evaluate the particle removal effectiveness (See, e.g., C. J. Gow, et al., “A Method for Evaluating Cleaning Techniques for the Removal of Particulates from Semiconductor Surfaces”, Proceedings of the Second International Symposium on Cleaning Technology, Electrochemical Society Inc., Volume 92-12, pages 366-371). However, previous evaluation methods are not particularly sensitive at detecting inadequacies in a wafer cleaning operation, especially with respect to wafer-to-wafer cross-contamination. As a result, it is often difficult to recognize and remedy deficiencies so as to improve the particle evacuation effectiveness and throughput of the cleaning operation.

A method capable of more accurate evaluation of the effectiveness of conventional semiconductor wafer cleaning operations, particularly the extent of wafer-to-wafer cross-contamination, would be beneficial. The results generated by such a method could be used to improve the particle evacuation efficiency of wafer cleaning operations so as to meet ever increasing industry standards for wafer surface cleanliness. Moreover, increased wafer cleaning effectiveness resulting from an improved evaluation method would increase the throughput of wafers produced having acceptable surface contamination and decrease manufacturing costs and decrease the quantity of waste products emitted into the environment.

### BRIEF SUMMARY OF THE INVENTION

Among the objects of the present invention, therefore, is to provide a method which improves the accuracy and sensitivity of evaluating the effectiveness of semiconductor wafer cleaning operations; to provide a method which is particularly suited to evaluate the extent of wafer-to-wafer cross-contamination; to provide a method which can be used to improve the particle evacuation effectiveness of semiconductor wafer cleaning operations; to provide a method which can be used to improve the design and operational parameters of semiconductor wafer cleaning tanks; to provide a method which can be used to increase the throughput of semiconductor wafer cleaning processes; to provide a method which can decrease the costs associated with producing semiconductor wafers; and to provide a method which can be used to decrease the quantity of waste products emitted into the environment.

Generally, the present invention is directed to a method for evaluating the particulate evacuating effectiveness of a wafer cleaning operation in which a cleaning liquid flows in a cleaning tank in contact with wafers to remove contaminant particles from the surface of the wafer. The method comprises inspecting a front side of a test wafer to determine the number of contaminant particles on the front side of the test wafer. The cleaning liquid is flowed in the cleaning tank and the inspected test wafer is immersed in the cleaning liquid within the cleaning tank, a zeta potential develops at the surface of the test wafer upon immersion in the cleaning liquid. A seed wafer having contaminant particles on the surface is also immersed in the cleaning liquid within the cleaning tank, contaminant particles liberated from the surface of the seed wafer into the cleaning liquid develop a zeta potential having a polarity opposite the polarity of the zeta potential at the surface of the test wafer in the cleaning liquid. The opposite polarity zeta potentials enhance the deposition of liberated contaminant particles onto the surface of the test wafer. The test wafer is removed from the cleaning liquid, dried and inspected to determine the number of contaminant particles on the front side of the dried test wafer.

In another embodiment, the method for evaluating the particulate evacuating effectiveness of a wafer cleaning operation comprises producing a flow of the cleaning liquid in the cleaning tank and immersing a test wafer in the cleaning liquid within the cleaning tank. The test wafer has a central axis and a surface comprising a front side and a back side generally perpendicular to the central axis and a circumferential edge joining the front side and the back side of the test wafer, the front side of the test wafer being substantially free of light point defects exceeding about 0.12 μm LSE in size. Upon immersion in the cleaning liquid, a zeta potential develops at the surface of the test wafer. A seed wafer having contaminant particles on the surface is also immersed in the cleaning liquid within the cleaning tank, contaminant particles liberated from the surface of the seed wafer into the cleaning liquid develop a zeta potential having a polarity opposite the polarity of the zeta potential at the surface of the test wafer in the cleaning liquid. The opposite polarity zeta potentials enhance the deposition of liberated contaminant particles onto the surface of the test wafer. The test wafer is removed from the cleaning liquid, dried and inspected to determine the number of contaminant particles on the front side of the dried test wafer.

Other objects and features of the present invention will be in part apparent and in part pointed out hereinafter.

### BRIEF DESCRIPTION OF THE DRAWINGS

FIG. 1 is a graph of the relative zeta potentials exhibited by a silicon wafer having a native silicon dioxide layer at the surface, iron oxide, titanium dioxide, aluminum oxide, and zinc oxide in an aqueous liquid as a function of pH of the liquid.

### DETAILED DESCRIPTION OF THE INVENTION

When an insoluble solid is contacted with a liquid medium, an electric double layer forms at the solid-liquid interface. The electric double layer comprises an array of either positive or negative ions attached to, or adsorbed on, the surface of the solid and a diffuse layer of ions of opposite charge surrounding the charged surface of the solid and extending into the liquid medium. The electric potential across the electric double layer is known as the zeta potential. Both the magnitude and polarity of the zeta potential for a particular solid-liquid system will tend to vary depending on the composition of the solid surface and the liquid, as well as other factors, including the size of the solid and the temperature and pH of the liquid. Although the polarity of the zeta potential may vary from one particle to another within a suspension of solid particles in a liquid, the polarity of the zeta potential for the suspension as a whole is characterized by the polarity of the surface charge attached to a predominant number of solid particles within the suspension. That is, a majority of the insoluble particles in the suspension will have either a positive or negative surface charge. The magnitude and polarity of the zeta potential for a suspension of solid particles in a liquid is calculated from the electrophoretic mobilities (i.e., the rates at which solid particles travel between charged electrodes placed in the suspension) and can be readily determined using commercially available microelectrophoresis apparatus.

In accordance with the present invention, an improved method has been developed for evaluating the particle evacuating effectiveness of a wafer cleaning operation of the type in which a cleaning liquid flows in a cleaning tank in contact with the wafers to be cleaned. The method of the present invention includes purposefully creating or enhancing attraction between one or more test wafers immersed in the liquid in the cleaning tank and contaminant particles introduced into the bath. As with any solid-liquid interface, a suspension of contaminant particles introduced into a cleaning liquid and a wafer surface in contact with a cleaning liquid will develop a zeta potential. The attractive force is created or enhanced by controlling the zeta potentials exhibited by the contaminant particles and the test wafer in the cleaning liquid so that they are of opposite polarity. Enhancing the attraction between the test wafer and contaminant particles in the bath tends to increase the number of particles deposited on the test wafer, thereby magnifying the effect of any deficiencies in the wafer cleaning operation. In this manner, the present invention provides a method more sensitive in detecting deficiencies in the particle evacuation effectiveness of a wafer cleaning operation.

The attractive force resulting from zeta potential interaction is only realized over relatively short distances (e.g., about 2 μm or less). As a result, the number and location of contaminant particles deposited on the test wafer are largely dependent on the flow characteristics (e.g., velocity and direction) of the cleaning liquid in the tank. By placing several test wafers in various positions in a cleaning tank and purposefully exacerbating the contamination of the test wafers in accordance with the present method, the resulting particle deposition patterns on the test wafers may be examined to determine possible deficiencies in the flow characteristics of the bath. Flow velocities and/or the positioning of liquid inlets and outlets in existing cleaning tanks may then be altered to improve particle evacuation effectiveness. The method of the present invention is also useful in evaluating and comparing the particle evacuation effectiveness of new or proposed cleaning tank systems. If a cleaning tank system includes a megasonic transducer array for directing sonic energy into the cleaning bath to enhance particle removal, characteristics of the sonic energy directed through the cleaning liquid may also be evaluated. For example, blind spots (i.e., portions of the cleaning tank which receive less than an optimum amount of sonic energy) may be identified by examining the particle deposition patterns on the test wafers. Based on the determined sonic energy characteristics, the time for replacing the transducer array may be determined and the positioning of the transducer array may be optimized when purchasing or constructing a new cleaning tank.

The method of the present invention may be applied in evaluating the particle evacuation effectiveness of various wafer cleaning operations employed during the course of semiconductor (e.g., silicon) wafer manufacture, including rinsing and etching (acid or alkaline) operations. Any wafer cleaning operation in which a cleaning liquid flows in a cleaning tank in contact with wafers to remove contaminant particles from the surface of the wafers can be evaluated using the method described herein. Cleaning tank systems lo conventionally used in such wafer cleaning operations are well known to those skilled in the art and include overflow recirculation tanks, quick dump rinse tanks, overflow rinse tanks and megasonic tanks with recirculation. Typically, cleaning tanks are constructed of quartz or polyvinylideneflouride and include one or more liquid inlets and outlets (e.g., an overflow) for flowing the cleaning liquid through the tank. Cleaning tanks used in wafer cleaning operations are commercially available from suppliers such as Veteq of Santa Anna, Calif., U.S.A. A plurality of wafers are typically loaded into slots in a carrier (i.e., each wafer is loaded individually into a slot) and then are immersed into the flow of cleaning liquid in the tank. The carriers which hold the wafers in the cleaning bath are typically constructed of quartz and are supplied by the manufacturers of the cleaning equipment such as Akrion of Allentown, Pa., U.S.A. Alternatively in some types of cleaning baths the wafers may be held in SEMI standard cassettes such as those commercially available from Entegris of Chaska, Minn., U.S.A.

In operation, cleaning liquid flows through the cleaning tank in contact with the wafers to be cleaned. As noted above, a variety of cleaning liquids are used in wafer cleaning and may comprise mixtures of ammonia, hydrogen peroxide and deionized water (SC1), mixtures of hydrochloric acid, hydrogen peroxide and deionized water (SC2), hydrofluoric acid, citric acid and/or deionized water. The chemical etching action of the cleaning liquid and/or sonic energy directed into the cleaning liquid liberate contaminant particles from the surface of the wafers immersed in the tank. The liberated contaminant particles are suspended in the cleaning liquid and carried away by the prevailing flows of the cleaning liquid in the cleaning tank. If the cleaning operation is conducted in an effective manner, the liberated contaminant particles are evacuated from the cleaning tank in the flow of cleaning liquid exiting the tank via an overflow or other liquid outlet. After the wafers have been immersed in the cleaning liquid for the requisite residence time necessary to clean the wafers as desired, the wafers are removed from the cleaning liquid and subjected to additional processing which may include rinsing and drying.

In the cleaning bath evaluation method of the present invention, a test wafer, contaminant particles and a cleaning liquid are selected so that the test wafer and contaminant particles develop zeta potentials of opposite polarity while immersed in the cleaning liquid flowing within a cleaning tank. The opposite polarity of the zeta potentials exhibited by the test wafer and the contaminant particles enhances the deposition of contaminant particles on the test wafer surface because contaminant particles carried close to the surface of the test wafer (i.e., within the Debye length) by the flow of the cleaning liquid within the cleaning tank, are attracted to and have an increased tendency to deposit on the surface of the test wafer. For example, if 18 MΩ deionized water is used as the cleaning liquid during evaluation of a wafer cleaning operation, there are very few ions present so that a relatively large diffuse layer develops around a solid immersed in deionized water. A calculation of the Debye length at 25° C. in 18 MΩ deionized water suggests that the diffuse layer of ions surrounding the charged surface of the solid may become approximately 1 μm thick. Accordingly, contaminant particles which come within about 1 to 2 μm of the surface of the test wafer will experience the attractive force associated with overlap of the oppositely polarized electric double layers. As the concentration of ions in the cleaning liquid increases, however, the thickness of the double layers generally decreases. Although the Debye length generally corresponds to the thickness of the diffuse layer, the forces associated with overlapping diffuse layers (attraction or repulsion) are relatively minor compared to the forces associated with the high concentration of ions attached to, or adsorbed on, the surface of the solids.

Preferably, the test wafer is a silicon wafer and the entire surface of the test wafer is covered with a native oxide layer (i.e., silicon dioxide, SiO₂) The test wafer has a central axis and the surface comprises a front side and a back side generally perpendicular to the central axis and a circumferential edge joining the front side and the back side of the test wafer. The diameter of the test wafer may be any conventional size (e.g., a nominal diameter of 200 mm, 300 mm or even larger) and is preferably selected to be representative of the wafers intended to be cleaned in the bath being evaluated.

So that the number of contaminant particles on the surface of the test wafer can be readily determined using a laser-based surface scanner system, the test wafer is preferably double-side polished. The polished surface of the test wafer is preferably characterized by a dry surface roughness that produces a light scattering of less than about 0.5 ppm as determined using a laser-based surface scanner system such as the SURFSCAN SP1 available from KLA-Tencor of Malpitas, Calif., U.S.A. or the CR-80 available from ADE Optical Systems of Charlotte, N.C., U.S.A.

Preferably, the test wafer has been cleaned and the front side of the test wafer is substantially free of light point defects (LPDs) such as particulate contamination and crystal originated pits. For example, the concentration of LPDs exceeding about 0.12 μm LSE in size on the front side of the test wafer is preferably less than about 0.1 defects/cm² (e.g., a 200 mm diameter test wafer has less than about 30 LPDs on the front side). More preferably, the concentration of LPDs exceeding about 0.12 μm LSE in size is less than about 0.06 defects/cm² (e.g., a 200 mm diameter test wafer has less than about 20 LPDs on the front side). Still more preferably, the concentration of LPDs exceeding about 0.12 μLSE in size is less than about 0.03 defects/cm² (e.g., a 200 mm diameter test wafer has less than about 10 LPDs on the front side). The number of LPDs on the test wafer may be determined using the above-mentioned laser-based surface scanner systems which can currently detect LPDs as small as about 0.06 μm LSE to about 0.08 μm LSE in size. Preferably, however, the laser-based surface scanner is set to detect particles larger than about 0.12 μm LSE in size. It is well known in the art that when measuring the number of LPDs on the surface of a wafer using a laser-based surface scanner, the actual size of the LPD is not determined. Rather, the light scatter of a LPD is compared to that of a reference particle of known diameter (e.g., a latex sphere with a diameter larger than about 0.12 μm) and the LPD density is measured in terms of latex sphere equivalent (LSE) based on the reference particle setting.

If it is not otherwise known whether the front side of the test wafer is substantially free of LPDs, the front side of the test wafer is inspected prior to being immersed into the cleaning liquid in order to determine the number of such defects on the front side of the test wafer. Additionally, a map or plot which indicates the location and concentration of particles/pits on the front side of the test wafer is preferably produced using the surface scanner system. The total LPD count and/or plot determined before immersing the test wafer in the cleaning liquid provides a baseline for comparing a LPD count and/or plot of the front side of the test wafer generated after the test wafer has been immersed in the cleaning liquid and exposed to contamination in accordance with the present invention.

Impending advances in wafer handling technology which handle a wafer by the circumferential edge rather than by the back side (e.g., the TBI-SP1 manufactured by KLA-Tencor) allow the back side of the test wafer to be substantially free of particulate contamination and/or crystallographic imperfections due to handling. Thus, provided the back side of the test wafer is polished, it can also be inspected for LPDs as set forth above and utilized in the evaluation method of the present invention.

For most oxides, including silicon dioxide such as the native oxide layer on the surface of the silicon test wafer, H⁺ and OH⁻ are potential-determining ions. Thus, it is the pH of a liquid in contact with a oxide solid that is the primary factor in determining the polarity of the zeta potential at the surface of the immersed solid. The pH at which an immersed solid has no zeta potential is referred to as the point of zero charge. A solid immersed in a liquid with a pH that is less than the point of zero charge exhibits a positive zeta potential. Conversely, a solid immersed in a liquid with a pH that is greater than the point of zero charge exhibits a negative zeta potential.

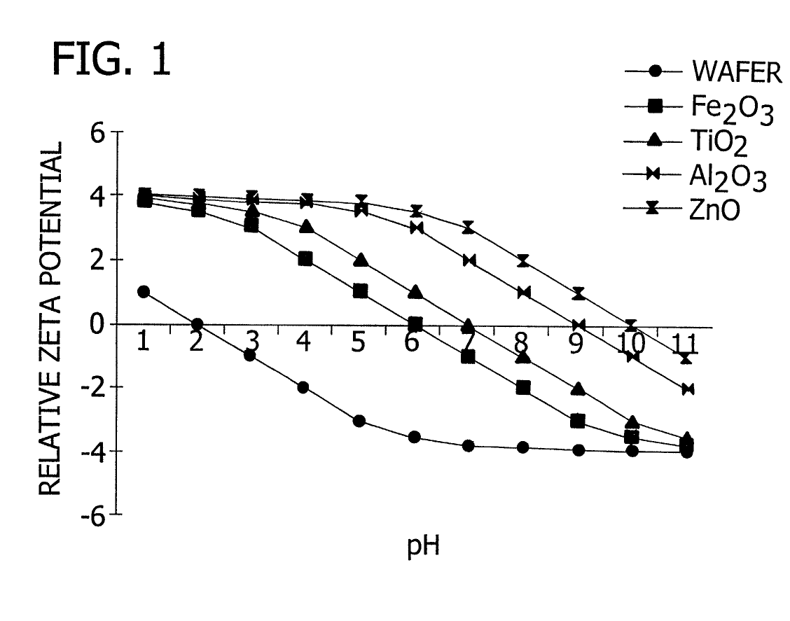

FIG. 1 is a graph of the relative zeta potentials exhibited by a silicon wafer having a native silicon dioxide layer at the surface and several metal oxides in an aqueous liquid as a function of the pH of the contacting liquid. As described below, this graph can be used in selecting the contaminant particles and/or pH of the cleaning liquid to use in the method of the present invention when a silicon wafer is used as the test wafer. As shown in FIG. 1, the point of zero charge for the silicon wafer having a native silicon dioxide layer at the surface occurs at a pH of about 2. Thus, when immersed in an aqueous liquid having a pH greater than about 2, the native oxide layer at the surface of a silicon test wafer develops a zeta potential with a negative polarity.

The contaminant particles used in the practice of the present invention are preferably comprised of metal oxides that develop a zeta potential with a positive polarity when immersed in a cleaning liquid having a pH greater than about 2 (i.e., opposite of the polarity of the zeta potential which develops on the native silicon dioxide layer at the surface of a silicon test wafer). Stated another way, metal oxides which have a point of zero charge at a pH greater than about 2 are preferably selected as the contaminant particles. Referring again to FIG. 1, the point of zero charge for iron oxide (Fe₂O₃) occurs at a pH of about 6, the point of zero charge for titanium dioxide (TiO₂) occurs at a pH of about 7, the point of zero charge for aluminum oxide (Al₂O₃) occurs at a pH of about 9, and the point of zero charge for zinc oxide (ZnO) occurs at a pH of about 10. Thus, a silicon test wafer and iron oxide contaminant particles develop zeta potentials with opposite polarities in an aqueous liquid having a pH of about 2 to about 6. A silicon test wafer and titanium dioxide contaminant particles develop zeta potentials with opposite polarities in an aqueous liquid having a pH of about 2 to about 7. A silicon test wafer and aluminum oxide contaminant particles develop zeta potentials with opposite polarities in an aqueous liquid having a pH of about 2 to about 9. A silicon test wafer and zinc oxide contaminant particles develop zeta potentials with opposite polarities in an aqueous liquid having a pH of about 2 to about 10.

The preferred contaminant particles comprise aluminum oxide because aluminum oxide develops a zeta potential with a polarity opposite that of a silicon test wafer when immersed in most of the conventional cleaning liquids used in wafer cleaning operations. For example, deionized water and ozonated deionized water have a pH of about 7, SC1 typically has a pH of about 8 to about 11, SC2 typically has a pH of about 2 to about 6, hydrofluoric acid etchant solutions typically have a pH of about 2 to about 5, and citric acid solutions typically have a pH of about 3 to about 6. Aluminum oxide contaminant particles are also preferred because they are widely used in the manufacture of silicon wafers (e.g., lapping grit typically comprises Al₂O₃ particles).

Although the method of the present invention is preferably performed under conditions which most closely simulate the cleaning operation being evaluated, parameters such as the pH of the cleaning liquid may be adjusted as necessary to accommodate more readily available contaminant particles without detriment to the results. For example, if the cleaning tank of the cleaning operation being evaluated normally contains a strongly basic cleaning liquid (e.g., having a pH of 12), in the evaluation method of the present invention, deionized water having a pH of about 7 may be substituted as the cleaning liquid so that a silicon test wafer and zinc oxide or aluminum oxide contaminant particles can be utilized.

As mentioned above, the preferred method for inspecting the surface of the test wafer for the presence of particulate contamination is with a laser-based surface scanner system. Accordingly, the extent to which the contaminant particles scatter light is more important than their size and/or shape. For example, contaminant particles which have a plate-like shape may be large yet scatter relatively little light compared to smaller, multi-faceted particles. The contaminant particles used in the method of the present invention preferably have a light scattering equivalency of about 0.12 μm to about 1.0 μm latex spheres as determined using a laser-based surface scanner system.

In accordance with the method of the present invention, the contaminant particles are introduced into the cleaning liquid by immersing a seed wafer having the contaminant particles on the surface in the cleaning liquid such that contaminant particles are liberated from the surface of the seed wafer into the cleaning liquid flowing in the cleaning tank. Introducing contaminant particles into the cleaning bath in this manner mimics wafer-to-wafer cross-contamination phenomena. The seed wafer may be comprised of any suitable material (e.g., silicon, alumina, titania, or zirconia). Preferably, the seed wafer is a silicon wafer. The diameter of the seed wafer may likewise be of any size that can be processed in the cleaning tank. Preferably, the nominal diameter of the seed wafer and the test wafer are the same and is selected to be representative of the wafers intended to be cleaned in the bath being evaluated.

At least a portion of the surface of the seed wafer is coated with contaminant particles. Preferably, both the front and back sides of the seed wafer are coated with contaminant particles. The concentration of contaminant particles on the seed wafer is typically so great that it cannot be determined using a laser-based surface scanner system. Preferably, the seed wafer is prepared by lapping a silicon wafer. After lapping, the wafer is typically rinsed in deionized water to remove caustic residue and dried. Provided no further cleaning of the wafer is performed, lapping grit (aluminum oxide contaminant particles) remains on the surface of the wafer and is liberated easily from the rough surface of the wafer when immersed into the cleaning liquid.

The method of the present invention is preferably employed under conditions which closely mimic the wafer cleaning operation being evaluated as it is typically performed during wafer manufacture. As such, the test wafer and the seed wafer are preferably loaded onto a wafer carrier prior to immersing the wafers in the cleaning liquid. Preferably, the wafer carrier is loaded to capacity so the flow characteristics of the cleaning liquid during the evaluation is similar to that achieved during a typical wafer cleaning operation. As such, the method of the present invention is preferably performed with a plurality of both test and seed wafers loaded into the carrier at various positions.

Although the number of test wafers and seed wafers can vary significantly, the seed wafers are preferably numerous enough to result in a concentration of contaminant particles in the cleaning liquid that is sufficient to deposit from about 800 to about 5,000 contaminant particles on each test wafer. Depositing more than about 5,000 contaminant particles per wafer saturates the laser-based surface scanner (i.e., the concentration of deposited particles is so great that a pattern cannot be distinguished). More preferably, about 1000 contaminant particles are deposited on each test wafer. Experimental results to date suggest that an appropriate number of contaminant particles are deposited on a test wafer when the concentration of contaminant particles in the cleaning liquid is about 100,000 per liter. The number of seed wafers necessary to achieve the foregoing particle counts is readily determined by trial and error. For example, in one particular cleaning tank designed for a wafer carrier holding 50 wafers having a nominal diameter of 200 mm, it was determined that about 1 to 6 seed wafers and more preferably 4 seed wafers provide a sufficient concentration of contaminant particles whereas 8 seed wafers saturate the test wafers with contaminant particles.

The remainder of the slots in the wafer carrier may be filled with test wafers. However, such practice is not preferred. Preferably, the number of test wafers is sufficient to make a reasonable determination of particle evacuation effectiveness without the expense of providing a test wafer in every open slot. In general, it is preferable to have a test wafer in the slots immediately adjacent each side of a seed wafer and a test wafer in a slot at a maximum distance from a seed wafer (e.g., about halfway between two seed wafers in the carrier). For a wafer cleaning operation accommodating a 50 wafer carrier having a single row of slots that position the wafers side-by-side in a parallel opposed manner, experimental results to date indicate that a proper evaluation can be made using 3 to 46 test wafers, and more preferably 15. Slots in the carrier not filled with a seed wafer or test wafer are preferably loaded with a filler wafer. Preferably, the filler wafers are silicon wafers that have the same nominal diameter as the seed and test wafers. Also, the filler wafers are preferably substantially free of particulate contamination in order to minimize the number of particles being introduced into the cleaning tank from any source other than the seed wafers. The use of filler wafers is advantageous because they may be reject wafers (e.g., an unacceptable level of crystallographic defects) and thus the cost associated with the use of test wafers is avoided.

The arrangement of the different types of wafers in the wafer carrier is an important factor in properly evaluating the particle evacuation effectiveness of a wafer cleaning operation. For example, proximity to the contamination source (e.g., the seed wafer) is an important consideration when evaluating light point defect plots of the test wafers. Preferably, the arrangement of the different types of wafers allows a reasonable determination of particle evacuation efficacy, cross-contamination and fluid flow characteristics throughout the entire cleaning tank without the expense and time requirements of evaluating the surface of test wafers placed in every slot of the carrier not filled with a seed wafer. Experimental results to date indicate that the aforementioned 50 wafer carrier is preferably loaded in the following manner: a test wafer is placed in slots 1, 5, 7, 14, 15, 17, 21, 25, 29, 31, 32, 39, 41, 45 and 50; a seed wafer is placed in slots 6, 16, 30, and 40; and a filler wafer is placed in slots 2 to 4, 8 to 13, 18 to 20, 22 to 24, 26 to 28, 33 to 38, 42 to 44 and 46 to 49. The foregoing load pattern can be adjusted proportionally for carriers having different wafer load capacities.

In the method of the present invention, the test wafer is preferably immersed in the cleaning liquid for a residence time substantially equivalent to the residence time employed during the wafer cleaning operation being evaluated. The test wafer is then removed from the cleaning liquid and dried.

If the cleaning liquid used in the evaluation method is an acid, a base or leaves a salt residue, the test wafer (along with the other wafers in the carrier) is preferably rinsed with deionized water (typically at about 17° C. to about 25° C.) before drying. Preferably, the test wafers, filler wafers and seed wafers are rinsed by a technique commonly referred to as a quick dump rinse. A quick dump rinse comprises placing the wafers (in the wafer carrier) in a cleaning tank filled with deionized water. As soon as the wafers are completely immersed, quick dump valves at the bottom of the cleaning tank are opened and the water rapidly flows from the tank. When the quick dump valves are opened, the wafers in the carrier are simultaneously sprayed with deionized water. Once the quick dump rinse tank is empty, the quick dump valves are closed and deionized water is pumped into the tank and the spray continues until the tank is full. Conventionally, the total dump time is about 2 seconds and the fill time is less than about 1 minute. Preferably, the fill time is about 30 seconds or less. Thus, the fill rate for the tank is preferably at least about the volume of the tank per minute, and more preferably twice the volume of the tank per minute. For example, a typical quick dump rinse tank has a volume of about 35 to about 50 liters, thus, the fill rate is preferably about 35 to 50 liters/minute, and more preferably about 70 to about 100 liters/minute. Preferably, the deionized water rinse comprises at least 2 quick dump rinses as described above, and more preferably 2 to 7 quick dump rinses.

Following the deionized water rinse, the test wafers are dried by any suitable method known in the art, such as by spin drying or IPA (i.e., drying with the aid of isopropyl alcohol). Preferably, the test wafers are dried by IPA. In general, IPA drying entails contacting a wet test wafer with isopropyl alcohol, which is miscible in water. The alcohol decreases the surface tension of water which decreases the contact angle between water droplets and the surface of the test wafer and causes the water to roll off the wafer surface. The remaining isopropyl alcohol evaporates.

There are three generally recognized methods of IPA drying: 1) Marangoni drying which entails pulling a wafer, submerged in water, through a water/isopropyl alcohol interface created by spraying alcohol across the top of the water; 2) the VAPOR JET process by SCP Global Technology, Boise, Idaho, U.S.A. which dries the wafer by blowing nitrogen gas containing about 1 to 2% isopropyl alcohol on the wafer surface; and 3) vapor drying which entails placing a carrier full of wafers in a cloud of heated isopropyl alcohol vapor, alcohol condenses on the wafers, displaces the water, and the water rolls off the wafer. Any of the foregoing IPA methods may be used in the practice of the present invention. However, there are benefits and disadvantages associated with each. For example, Marangoni and VAPOR JET generally use significantly less alcohol than vapor drying. Also, Marangoni and VAPOR JET are generally slower than vapor drying, and as a result, two or three dryers are usually necessary to avoid back-ups. Lastly, Marangoni and VAPOR JET tend to leave water spots on the wafer surface. In view of the foregoing, the test wafer is preferably dried using the IPA vapor method. Preferably, the temperature of the isopropyl alcohol cloud is about 80 to about 85° C. Preferably, the test wafer is left in the cloud until it equilibrates with the temperature of the cloud. Typically, this takes about 3 to about 10 minutes. However, if a low mass wafer carrier is used, the time can be reduced to about 2 to about 5 minutes.

After being contaminated with particles in accordance with the method of the present invention, a LPD count and/or plot of at least one dried test wafer is obtained using a laser-based surface scanner system. Based on the LPD count and/or plot of the test wafer, the following observations, among others, may be made: (a) the effect distance from the seed wafer has on the degree of contamination of the test wafer (e.g., the seed wafer and test wafer in immediately adjacent slots of the carrier versus being separated by five or more slots away); (b) the variation in particle contamination based on the position of the test wafer in the cleaning tank during the evaluation method; (c) the degree of contamination due to orientation of the test wafer relative to the seed wafer (e.g., does the front side of the test wafer become more or less contaminated when facing toward or away from the seed wafer); (d) the degree of contamination attributable to known conditions within the cleaning tank (e.g., obstructions, position or angle of cleaning liquid inlet or recirculation nozzles); and (e) the degree of contamination due to the rate the wafers are withdrawn from the cleaning tank.

If megasonic energy was used to enhance wafer cleaning, the effectiveness of the megasonic cleaning may also be evaluated by the method of the present invention. For a large solid such as a test wafer, the density of the diffuse layer of ions surrounding the charged solid is substantially less than that of a small solid such as a contaminant particle. When megasonic energy is introduced into the cleaning bath, the density of the diffuse layer of ions surrounding the surface of a solid decreases and in the case of a large solid (e.g., test wafer) the density of the diffuse layer decreases to such an extent that it is essentially nonexistent. Thus, any repulsive forces associated with the ions in the diffuse layer surrounding the test wafer (typically having a positive polarity) and the ions adsorbed on the surface of the contaminant particles (typically having a positive polarity) are reduced. This increases the dominant attractive force between the ions adsorbed on the surface of the test wafer (typically negative) and the ions adsorbed on the surface of the contaminant particles (typically having a positive polarity) resulting in increased contaminant particle deposition. The number and location of contaminant particles on a LPD plot of a wafer exposed to megasonic energy illustrates the intensity of the sonic waves as a function of position on the wafer (i.e., the greater the concentration of contaminant particles the greater the sonic energy). By evaluating several test wafers, “blind spots” along the length of the transducer that negatively impact the effectiveness of the removal of particles from the surface of wafers immersed in the cleaning liquid may be detected.

Based on the foregoing observations regarding the number and/or location of contaminant particles deposited on the surface of the test wafer, an informed decision as to what actions may be implemented to improve the particle evacuation effectiveness of the wafer cleaning operation and reduce wafer contamination may be made. For example, the cleanliness of treated wafers in an existing cleaning tank may be improved by changing the velocity of the flow of cleaning liquid in the tank and/or adjusting the power delivered to a megasonic transducer array. After the desired action is implemented, the effectiveness of the change may be assessed using the method of the present invention. Thus, the particle evacuation effectiveness of a wafer cleaning operation can be enhanced through multiple iterations of the method of the present invention. The observations are also valuable when designing a new cleaning tank (e.g., the placement of liquid inlets and outlets and the megasonic transducer array may be changed to improve the particle evacuation effectiveness of the wafer cleaning operation.

After the method of the present invention has been completed, the cleaning liquid is preferably emptied from the cleaning tank and the recirculating system and replaced with fresh cleaning liquid to reduce the risk of contamination of later processed wafers. Preferably, a particle addition test comprising determining the number of particles on a wafer, processing the wafer in the cleaning tank and then determining the number of particles on the wafer is performed. Preferably, the wafer has a zero particle per wafer pass (PPWP). If the PPWP is greater than zero, then the tank is preferably rinsed and the particle addition test performed again until satisfactory results achieved.

In view of the above, it will be seen that the several objects of the invention are achieved and other advantageous results attained. It is intended that all matter contained in the above description shall be interpreted as illustrative and not in a limiting sense.

When introducing elements of the present invention or the preferred embodiment(s) thereof, the articles “a”, “an”, “the” and “said” are intended to mean that there are one or more of the elements. The terms “comprising”, “including” and “having” are intended to be inclusive and mean that there may be additional elements other than the listed elements.

What is claimed is:

1. A method for evaluating the particulate evacuating effectiveness of a wafer cleaning operation in which a cleaning liquid flows in a cleaning tank in contact with wafers to remove contaminant particles from the surface of the wafers, the method comprising:
inspecting a front side of a test wafer to determine the number of contaminant particles on the front side of the test wafer;
producing a flow of the cleaning liquid in the cleaning tank;
immersing the inspected test wafer in the cleaning liquid within the cleaning tank, a zeta potential developing at the surface of the test wafer upon immersion in the cleaning liquid;
immersing a seed wafer in the cleaning liquid within the cleaning tank, the seed wafer having contaminant particles on the surface of the seed wafer, contaminant particles liberated from the surface of the seed wafer into the cleaning liquid developing a zeta potential having a polarity opposite the polarity of the zeta potential at the surface of the test wafer in the cleaning liquid to enhance the deposition of liberated contaminant particles onto the surface of the test wafer;
removing the test wafer from the cleaning liquid in the cleaning tank;
drying the test wafer after it is removed from the cleaning liquid; and
inspecting the front side of the dried test wafer to determine the number of contaminant particles on the front side of the dried test wafer.

2. The method as set forth in claim 1 wherein inspection of the front side of the test wafer prior to immersing the test wafer in the cleaning liquid and after drying the test wafer produces a plot of the contaminant particles on the front side of the test wafer.

3. The method as set forth in claim 1 further comprising inspecting the back side of the test wafer prior to immersing the test wafer in the cleaning liquid and inspecting the back side of the dried test wafer to determine the number of contaminant particles on the back side of the test wafer.

4. The method as set forth in claim 3 wherein inspection of the back side of the test wafer prior to immersing the test wafer in the cleaning liquid and after drying the test wafer produces a plot of contaminant particles on the back side of the test wafer.

5. The method as set forth in claim 1 further comprising rinsing the surface of the test wafer with deionized water after it is removed from the cleaning liquid in the cleaning tank and prior to drying the test wafer.

6. The method as set forth in claim 1 wherein the wafer cleaning operation being evaluated includes introducing sonic energy into the cleaning liquid flowing in the cleaning tank, the method further comprises introducing sonic energy into the cleaning liquid while the test wafer and the contaminant wafer are immersed in the cleaning liquid within the cleaning tank.

7. The method as set forth in claim 1 wherein the polarity of the zeta potential at the surface of the test wafer immersed in the cleaning liquid is negative and the polarity of the zeta potential of the liberated contaminant particles in the cleaning liquid is positive.

8. The method as set forth in claim 7 wherein the test wafer and the seed wafer are silicon wafers.

9. The method as set forth in claim 8 wherein the front side of the test wafer has a surface roughness that produces a light scattering of less than about 0.5 ppm.

10. The method as set forth in claim 8 wherein the concentration of light point defects greater than about 0.12 μm LSE on the front side of the test wafer is less than about 0.1 defects/cm² prior to immersion of the test wafer in the cleaning liquid.

11. The method as set forth in claim 8 wherein the concentration of light point defects greater than about 0.12 μm LSE on the front side of the test wafer is less than about 0.06 defects/cm² prior to immersion of the test wafer in the cleaning liquid.

12. The method as set forth in claim 8 wherein the concentration of light point defects greater than about 0.12 μm LSE on the front side of the test wafer is less than about 0.03 defects/cm² prior to immersion of the test wafer in the cleaning liquid.

13. The method as set forth in claim 8 wherein the contaminant particles are selected from the group consisting of iron oxide, titanium dioxide, aluminum oxide and zinc oxide.

14. The method as set forth in claim 8 wherein the contaminant particles have a light scattering equivalency of from about 0.12 μm to about 1.0 μm latex spheres.

15. The method as set forth in claim 8 wherein the cleaning liquid is selected from the group consisting of water, deionized water, ozonated deionized water, hydrogen peroxide, ammonia, nitric acid, hydrofluoric acid, citric acid and mixtures thereof.

16. The method as set forth in claim 8 wherein the cleaning liquid consists essentially of deionized water.

17. The method as set forth in claim 8 wherein the cleaning liquid consists essentially of a mixture of ammonia, hydrogen peroxide and deionized water.

18. The method as set forth in claim 1 further comprising immersing a filler wafer in the cleaning liquid within the cleaning tank.

19. The method as set forth in claim 18 wherein the filler wafer is a silicon wafer.

20. The method as set forth in claim 18 wherein the test wafer, seed wafer and filler wafer are loaded into a carrier having a single row of slots that are configured to hold the test wafer, seed wafer and filler wafer in a parallel opposed relationship.

21. The method as set forth in claim 20 wherein a plurality of test wafers, seed wafers and filler wafers are loaded into the carrier and then immersed in the cleaning liquid.

22. The method as set forth in claim 21 wherein the total number of test wafers, seed wafers and filler wafers corresponds to the optimum wafer capacity of the cleaning tank.

23. The method as set forth in claim 22 wherein the carrier has 50 slots and test wafers, seed wafers and filler wafers are loaded onto the carrier such that the test wafers occupy slots 1, 5, 7, 14, 15, 17, 21, 25, 29, 31, 32, 39, 41, 45 and 50, the seed wafers occupy slots 6, 16, 30, and 40 and the filler wafers occupy slots 2 to 4, 8 to 13, 18 to 20, 22 to 24, 26 to 28, 33 to 38, 42 to 44 and 46 to 49.

24. A method for evaluating the particulate evacuating effectiveness of a wafer cleaning operation in which a cleaning liquid flows in a cleaning tank in contact with wafers to remove contaminant particles from the surface of the wafers, the method comprising:
producing a flow of the cleaning liquid in the cleaning tank;
immersing a test wafer in the cleaning liquid within the cleaning tank, the test wafer having a central axis and a surface comprising a front side and a back side generally perpendicular to the central axis and a circumferential edge joining the front side and the back side of the test wafer, the front side of the test wafer being substantially free of light point defects exceeding about 0.12 μm LSE in size, a zeta potential developing at the surface of the test wafer upon immersion in the cleaning liquid;
immersing a seed wafer in the cleaning liquid within the cleaning tank, the seed wafer having contaminant particles on the surface of the seed wafer, contaminant particles liberated from the surface of the seed wafer into the cleaning liquid developing a zeta potential having a polarity opposite the polarity of the zeta potential at the surface of the test wafer in the cleaning liquid to enhance the deposition of liberated contaminant particles onto the surface of the test wafer;
removing the test wafer from the cleaning liquid in the cleaning tank;
drying the test wafer after it is removed from the cleaning liquid; and
inspecting the front side of the dried test wafer to determine the number of contaminant particles on the front side of the dried test wafer.
